(19) United States
(12) Patent Application Publication
(10) Pub. No.: US 2025/0157787 A1
(43) Pub. Date: May 15, 2025

(54) PLASMA PROCESSING APPARATUS AND END POINT DETECTION METHOD

(71) Applicant: Tokyo Electron Limited, Tokyo (JP)

(72) Inventor: Masakazu HAYASHI, Miyagi (JP)

(73) Assignee: Tokyo Electron Limited, Tokyo (JP)

(21) Appl. No.: 19/019,808

(22) Filed: Jan. 14, 2025

Related U.S. Application Data
(63) Continuation of application No. PCT/JP2023/026144, filed on Jul. 14, 2023.

(30) Foreign Application Priority Data
Jul. 21, 2022 (JP) 2022-116160

(51) Int. Cl. H01J 37/24; H01J 37/32

(52) U.S. Cl. CPC H01J 37/243; H01J 37/32165; H01J 37/32302; H01J 2237/3343

(57) ABSTRACT

A power supply supplies, to a chamber, periodic power for forming a gas supplied into the chamber into a plasma, a power level of the periodic power being changed for each period during one cycle. Circuitry is configured to detect an end point of a first etching based on at least one of a voltage, a current, or a phase difference between the voltage or the current measured by a sensor at a first timing during the one cycle. The circuitry is configured to detect an end point of a second etching based on at least one of a voltage, a current, or a phase difference between the voltage or the current measured by the sensor at a second timing different from the first timing during the one cycle.

### CROSS-REFERENCE TO RELATED APPLICATIONS

This application is a bypass continuation application of international application No. PCT/JP2023/026144 having an international filing date of Jul. 14, 2023, and designating the United States, the international application being based upon and claiming the benefit of priority from Japanese Patent Application No. 2022-116160, filed on Jul. 21, 2022, the entire contents of each are incorporated herein by reference.

### TECHNICAL FIELD

The present disclosure relates to a plasma processing apparatus and an end point detection method.

### BACKGROUND

Patent Document 1 discloses a technique of detecting an end point (endpoint) of etching based on a signal measured by a VI probe during plasma etching.

### CITATION LIST

### Patent Documents

Patent Document 1: US2005/0217795A

### SUMMARY

The present disclosure provides a technique for accurately detecting an end point of etching.

A plasma processing apparatus according to one aspect of the present disclosure includes: a chamber, an electrode, a sensor, a gas supply, a power supply, and circuitry. The chamber has a stage inside on which a substrate is placeable. The electrode is disposed in the chamber. The sensor is provided on the electrode or on an interconnect connected to the electrode, and measures either a voltage or a current. The gas supply supplies a gas to be formed into a plasma into the chamber. The power supply supplies, to the chamber, periodic power for forming the gas supplied into the chamber into the plasma, a power level of the periodic power being changed for each period during one cycle. The circuitry detects an end point of a first etching based on at least one of a voltage, a current, or a phase difference between the voltage or the current measured by the sensor at a first timing during the one cycle. The circuitry detects an end point of a second etching based on at least one of a voltage, a current, or a phase difference between the voltage or the current measured by the sensor at a second timing different from the first timing during the one cycle.

According to the present disclosure, the end point of etching can be accurately detected.

### BRIEF DESCRIPTION OF DRAWINGS

FIG. 1 is a diagram illustrating an example of a schematic configuration of a plasma processing system according to an embodiment;

FIG. 2 is a block diagram illustrating an example of a schematic configuration of a controller according to the embodiment;

FIG. 3A is a diagram illustrating an example of changes in periodic power supplied from a power supply according to the embodiment;

FIG. 3B is a diagram illustrating an example of changes in periodic power supplied from the power supply according to the embodiment;

FIG. 4 is a diagram illustrating detection of an end point of etching according to the embodiment;

FIG. 5 is a diagram illustrating detection of an end point of etching in the related art;

FIGS. 6A and 6B are diagrams illustrating examples of a schematic configuration of a substrate that is an etching target according to the embodiment;

FIG. 7 is a diagram illustrating an example of periodic power supplied from the power supply according to the embodiment;

FIGS. 8A and 8B are diagrams illustrating examples of a schematic configuration of an etched substrate W according to the embodiment;

FIG. 9 is a diagram schematically illustrating changes in signals measured by a measurement unit according to the embodiment;

FIG. 10 is a diagram illustrating an example of detection of an end point of etching of a first film and a second film according to the embodiment;

FIG. 11A is a diagram schematically illustrating an example of changes in periodic power supplied from the power supply according to the embodiment;

FIG. 11B is a diagram schematically illustrating an example of changes in periodic power supplied from the power supply according to the embodiment;

FIG. 12 is a diagram illustrating an example of detecting an end point of etching according to the embodiment;

FIG. 13 is a diagram illustrating an example of detecting an end point of etching according to the embodiment; and

FIG. 14 is a diagram illustrating an example of a processing order of an end point detection method according to the embodiment.

### DETAILED DESCRIPTION

Hereinafter, an embodiment of a plasma processing apparatus and an end point detection method disclosed in the present application will be described in detail with reference to the drawings. The disclosed plasma processing apparatus and end point detection method are not limited to the present embodiment.

In plasma etching, in order to prevent excessive etching and prevent fluctuations in a pattern shape, a method of detecting an end point of the etching in real time and stopping etching processing is applied. As a method of detecting an end point of etching in the related art, for example, a method of detecting the end point of the etching based on a change in an emission intensity of a plasma during the etching using an optical emission sensor (OES) is known. Moreover, there is a method of detecting an end point of etching based on a signal measured by a VI probe during plasma etching. For example, the end point of the etching is detected based on a moving average of signals continuously measured by the VI probe.

Multi-colored etching in which three or more types of film types are collectively etched has been studied. In the multi-colored etching, periodic power in which a power level is changed for each period during one cycle is supplied to a chamber to generate a plasma, and the etching is performed.

However, in the method of detecting the end point of the etching in the related art, when power periodically fluctuates, the end point of the etching cannot be accurately detected. Therefore, a technique of accurately detecting an end point of etching is needed.

### Embodiment

### System Configuration

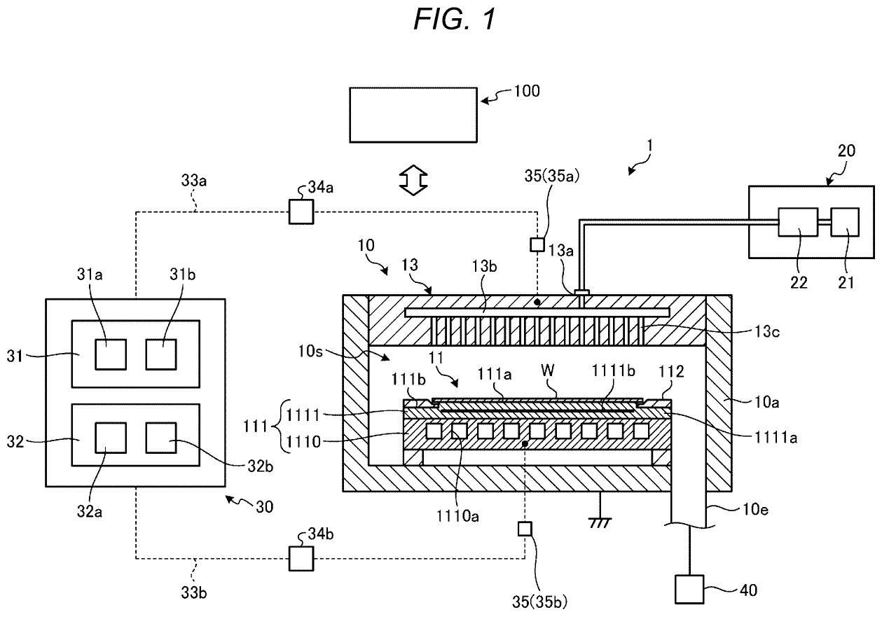

An example of a plasma processing apparatus according to the present disclosure will be described. In the following embodiment, a case where the plasma processing apparatus according to the present disclosure is a plasma processing system having a system configuration will be described as an example. FIG. 1 is a diagram illustrating an example of a schematic configuration of the plasma processing system according to the embodiment.

Hereinafter, a configuration example of the plasma processing system will be described. FIG. 1 is a diagram illustrating a configuration example of a capacitively-coupled plasma processing apparatus.

The plasma processing system includes a capacitively-coupled plasma processing apparatus 1 and a controller 100. The capacitively-coupled plasma processing apparatus 1 includes a plasma processing chamber 10, a gas supply 20, a power supply 30, and an exhaust system 40. The plasma processing apparatus 1 further includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas into the plasma processing space 10s, and at least one gas exhaust port for exhausting the gas from the plasma processing space 10s. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a, which supports a substrate W, and an annular region 111b, which supports the ring assembly 112. A wafer is an example of the substrate W. The annular region 111b of the main body 111 surrounds the central region 111a of the main body 111 in a plan view. The substrate W is placed on the central region 111a of the main body 111, and the ring assembly 112 is disposed on the annular region 111b of the main body 111 so as to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a, and an electrostatic electrode 1111b disposed in the ceramic member 1111a. The ceramic member 1111a has the central region 111a. In one embodiment, the ceramic member 1111a also has the annular region 111b. Another member that surrounds the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power supply 31 and/or a direct current (DC) power supply 32 to be described below may be disposed inside the ceramic member 1111a. In this case, at least one RF/DC electrode functions as the lower electrode. When a bias RF signal and/or DC signal, which will be described later, are supplied to the at least one RF/DC electrode, the RF/DC electrode is also called a bias electrode. The conductive member of the base 1110 and at least one RF/DC electrode may function as a plurality of lower electrodes. The electrostatic electrode 1111b may instead function as the lower electrode. Accordingly, the substrate support 11 includes at least one lower electrode.

The ring assembly 112 includes one or more annular members. In one embodiment, the one or more annular members include one or more edge rings and at least one cover ring. The edge ring is formed of a conductive material or an insulating material, and the cover ring is formed of an insulating material.

The substrate support 11 may further include a temperature control module configured to adjust a temperature of at least one of the electrostatic chuck 1111, the ring assembly 112, and the substrate W to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed in the base 1110, and one or more heaters are disposed in the ceramic member 1111a of the electrostatic chuck 1111. The substrate support 11 may further include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s via the gas introduction ports 13c. The shower head 13 further includes at least one upper electrode. The gas introduction unit may include, in addition to the shower head 13, one or more side gas injectors (SGI) that are attached to one or more openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power supply 30 includes the RF power supply 31 coupled to the plasma processing chamber 10 via at least one impedance matching circuit. The RF power supply 31 is configured to supply at least one RF signal (RF power) to the at least one lower electrode and/or the at least one upper electrode. Accordingly, the plasma is formed from at least one processing gas supplied into the plasma processing space 10s. Accordingly, the RF power supply 31 may function as at least a portion of a plasma generator configured to generate a plasma from one or more processing gases in the plasma processing chamber 10. Further, supplying the bias RF signal to at least one lower electrode can generate a bias potential in the substrate W to attract an ion component in the formed plasma to the substrate W.

In one embodiment, the RF power supply 31 includes a first RF generator 31a and a second RF generator 31b. The first RF generator 31a is coupled to the at least one lower electrode and/or the at least one upper electrode via the at least one impedance matching circuit, and is configured to generate a source RF signal (source RF power) for plasma generation. In one embodiment, the source RF signal has a frequency within a range from 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate a bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 31b may be configured to generate a plurality of bias RF signals having different frequencies. The generated one or more bias RF signals are supplied to the at least one lower electrode. Further, in various embodiments, at least one of the source RF signal and the bias RF signal may be pulsed.

For example, the first RF generator 31a is electrically connected to a conductive member of the shower head 13 via a conductive portion 33a such as an interconnect. The conductive portion 33a includes an impedance matching circuit 34a. The impedance matching circuit 34a matches output impedance of the first RF generator 31a and input impedance on a load side (shower head 13 side). The first RF generator 31a supplies first power having a first frequency for generating a plasma to the conductive member of the shower head 13. For example, the first RF generator 31a supplies the above-described source RF signal as the first power to the conductive member of the shower head 13 via the conductive portion 33a and the impedance matching circuit 34a. The source RF signal is, for example, 60 MHz. The conductive member of the shower head 13 functions as an electrode. When the source RF signal is supplied, a high-density plasma is generated in the plasma processing chamber 10.

For example, the second RF generator 31b is electrically connected to the conductive member of the base 1110 of the substrate support 11 via a conductive portion 33b such as an interconnect. The conductive portion 33b includes an impedance matching circuit 34b. The impedance matching circuit 34b matches output impedance of the second RF generator 31b and input impedance on a load side (substrate support 11 side). The second RF generator 31b supplies second power having a second frequency lower than the first frequency for attracting an ion component in the plasma into the substrate W to the conductive member of the substrate support 11. For example, the second RF generator 31b supplies the bias RF signal described above as the second power to the conductive member of the substrate support 11 via the conductive portion 33b and the impedance matching circuit 34b. The bias RF signal is set to, for example, 40 MHz. The conductive member of the substrate support 11 functions as an electrode. When the bias RF signal is supplied, the ion component in the plasma generated in the plasma processing chamber 10 is attracted into the substrate W.

In the plasma processing apparatus 1, a measurement unit 35, for example a sensor, that measures either a voltage or a current is provided on the electrode disposed in the plasma processing chamber 10 or an interconnect connected to the electrode. In the plasma processing apparatus 1 according to the present embodiment, a measurement unit 35a is provided in the conductive portion 33a connected to the conductive member of the shower head 13. In the plasma processing apparatus 1 according to the present embodiment, a measurement unit 35b is provided in the conductive portion 33b connected to the conductive member of the substrate support 11. The measurement units 35a and 35b each include a probe that detects a current or a voltage. For example, the measurement units 35a and 35b each include a voltage sensor and/or a current sensor. The measurement units 35a and 35b measure voltages or currents. The measurement unit 35a measures a voltage or a current of the conductive portion 33a through which the source RF signal flows. The measurement unit 35a outputs signals indicating the measured voltage or current to the controller 100. The measurement unit 35b measures a voltage or a current of the conductive portion 33b through which the bias RF signal flows. The measurement unit 35b outputs signals indicating the measured voltage or current to the controller 100.

The power supply 30 may include the DC power supply 32 coupled to the plasma processing chamber 10. The DC power supply 32 includes a first DC generator 32a and a second DC generator 32b. In one embodiment, the first DC generator 32a is configured to be connected to at least one lower electrode to generate a first DC signal. The generated first bias DC signal is applied to at least one lower electrode. In one embodiment, the second DC generator 32b is configured to be connected to at least one upper electrode to generate a second DC signal. The generated second DC signal is applied to the at least one upper electrode.

In various embodiments, at least one of the first and second DC signals may be pulsed. In this case, a sequence of voltage pulses is applied to at least one lower electrode and/or at least one upper electrode. The voltage pulses may each have a rectangular, trapezoidal, or triangular waveform or a combination thereof. In one embodiment, a waveform generator that generates a sequence of voltage pulses from a DC signal is connected between the first DC generator 32a and the at least one lower electrode. Accordingly, the first DC generator 32a and the waveform generator configure a voltage pulse generator. When the second DC generator 32b and the waveform generator constitute the voltage pulse generator, the voltage pulse generator is connected to the at least one upper electrode. The voltage pulse may have a positive polarity or a negative polarity. The sequence of the voltage pulses may include one or more positive voltage pulses and one or more negative voltage pulses in one cycle. The first DC generator 32a and the second DC generator 32b may be provided in addition to the RF power supply 31, or the first DC generator 32a may be provided in place of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

The controller 100 collectively controls an operation of the plasma processing apparatus 1 configured as described above.

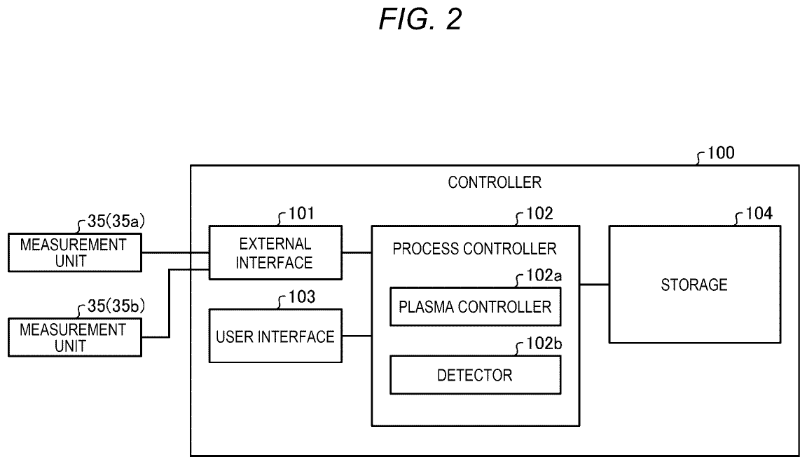

FIG. 2 is a block diagram illustrating an example of a schematic configuration of the controller 100 according to the embodiment.

The controller 100 is, for example, a computer, and controls each part of the plasma processing apparatus 1. The operation of the plasma processing apparatus 1 is collectively controlled by the controller 100. The controller 100 controls the plasma processing apparatus 1 to perform various processes to be described in the present disclosure. The controller 100 includes an external interface 101, a process controller 102, a user interface 103, and a storage 104.

The external interface 101 can communicate with each part of the plasma processing apparatus 1 to input and output various types of data. Signals indicating the voltages or currents measured by the measurement unit 35 are input to the external interface 101. In the present embodiment, signals indicating the voltages or currents measured by the measurement units 35a and 35b are input to the external interface 101.

The process controller 102 includes a central processing unit (CPU) and controls each part of the plasma processing apparatus 1.

In embodiments, the controller 100 and/or the process controller 102 is/are at least embodied by circuitry. For example, their functionality may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein.

The user interface 103 includes a keyboard through which a process administrator inputs commands to manage the plasma processing apparatus 1, and a display that provides visualization of an operating status of the plasma processing apparatus 1.

The storage 104 stores control programs (software) for implementing various types of processing to be executed by the plasma processing apparatus 1 under control of the process controller 102, and recipes in which processing condition data and the like are stored. The control program or recipe may be used by being stored in a computer-readable computer recording medium (for example, a hard disk, an optical disk such as a DVD, a flexible disk, and a semiconductor memory). It is also possible to transmit the control program or the recipe from another apparatus at any time through, for example, a dedicated line and use the control program or recipe on-line.

The process controller 102 has an internal memory for storing programs and data, reads a control program stored in the storage 104, and executes processing of the read control program. The process controller 102 functions as various processors when the control program operates. For example, the process controller 102 has functions of a plasma controller 102a and a detector 102b. In the present embodiment, a case where the process controller 102 has the functions of the plasma controller 102a and the detector 102b will be described as an example. However, the functions of the plasma controller 102a and the detector 102b may be implemented in a distributed manner by a plurality of controllers.

The plasma controller 102a controls plasma processing. For example, the plasma controller 102a controls the exhaust system 40 to exhaust an inside of the plasma processing chamber 10 to a desired vacuum level. The plasma controller 102a controls the gas supply 20 to introduce a processing gas for etching from the gas supply 20 into the plasma processing space 10s. The plasma controller 102a controls the power supply 30, and supplies a source RF signal and a bias RF signal from the first RF generator 31a and the second RF generator 31b in accordance with the introduction of the processing gas, thereby generating a plasma in the plasma processing chamber 10.

The plasma processing apparatus 1 according to the present embodiment performs multi-colored etching. The plasma controller 102a controls the power supply 30 to supply power from the power supply 30 for forming the processing gas for etching supplied to the plasma processing chamber 10 into a plasma. For example, the plasma controller 102a controls the power supply 30 to supply periodic power to the plasma processing chamber 10, a power level of the periodic power being changed for each period during one cycle. The RF power supply 31 supplies periodic power of at least one of the source RF signal and the bias RF signal, a power level of the periodic power being changed for each period during one cycle. For example, the plasma controller 102a controls the RF power supply 31 to supply a periodic source RF signal and bias RF signal, power levels of which are changed for each period during one cycle, from the first RF generator 31a and the second RF generator 31b. Frequencies of the source RF signal and the bias RF signal are, for example, 100 Hz to 10 kHz. Hereinafter, of the source RF signal and the bias RF signal, the source RF signal having a high frequency will also be referred to as high frequency (HF), and a bias RF signal having the low frequency will also be referred to as low frequency (LF).

In the multi-colored etching, a power level suitable for etching of an etching target film is controlled for each period during one cycle. In the multi-colored etching, an etching target film in which etching is mainly performed is defined for a period during one cycle, and a power level is controlled in accordance with the etching target film for each period during one cycle, thereby obtaining desired etching characteristics.

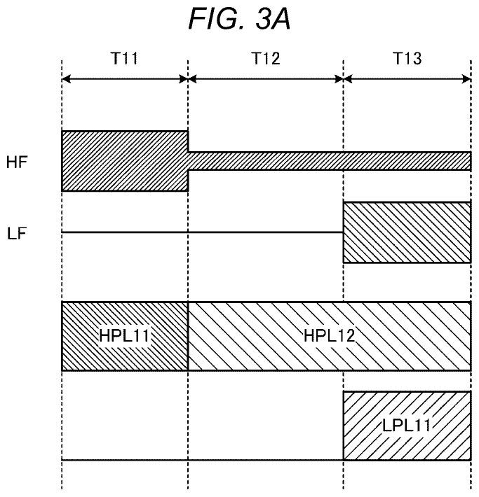

FIGS. 3A and 3B are diagrams illustrating examples of changes in periodic power supplied from the power supply 30 according to the embodiment. FIGS. 3A and 3B illustrate examples of changes in a power level for each period during one cycle of the periodic power supplied from the power supply 30. “HF” indicates a change in power of source RF signal power in amplitude. “LF” indicates a change in power of the bias RF signal power in amplitude.

In FIG. 3A, one cycle is divided into periods T11 to T13. The source RF signal is set to HPL11 where the power is large in the period T11, and HPL12 where the power is smaller than the HPL11, in the periods T12 and T13. The bias RF signal is set to zero in the periods T11 and T12, and LPL11 where the power is large in the period T13.

In FIG. 3B, one cycle is divided into periods T21 to T24. The source RF signal gradually decreases from HPL21 where the power is large to HPL24 where the power is small during the periods T21 to T24. The bias RF signal gradually increases from LPL21 where the power is small to LPL24 where the power is large during the periods T21 to T24.

Reference will again be made to FIG. 2. The detector 102b detects an end point of the plasma processing based on a voltage or a current of a signal input from the measurement unit 35. For example, the detector 102b detects the end point of the plasma processing based on a change in at least one of a voltage, a current, and a phase difference between the voltage and the current measured by the measurement units 35a and 35b at a timing synchronized with a cycle of periodic power supplied from the power supply 30 to the plasma processing chamber 10. In the present embodiment, the detector 102b detects the end point of the etching based on a change in at least one of a voltage, a current, and a phase difference between the voltage and the current measured by the measurement units 35a and 35b at a timing synchronized with a power cycle. The detector 102b detects the end point of the etching based on a change in at least one of a voltage, a current, and a phase difference between the voltage and the current measured by the measurement units 35a and 35b at a timing when a combination of the supplied source RF signal and bias RF signal contributes most to the etching and selectivity. For example, in the present embodiment, a period in which the bias RF signal is supplied contributes most to the etching and the selectivity. The detector 102b detects the end point of the etching based on a change in at least one of a voltage, a current, and a phase difference between the voltage and the current measured by the measurement unit 35 in a period when the bias RF signal is supplied.

The plasma controller 102a controls the plasma processing based on a detection result from the detector 102b. For example, the plasma controller 102a controls a power cycle and a power level for each period of one cycle based on the detection result of the detector 102b. For example, the plasma controller 102a shortens or deletes a period in one cycle of the power corresponding to the etching target film in which the end point of the etching is detected. Alternatively, the plasma controller 102a allocates, in one cycle of the power, a period corresponding to the etching target film in which the end point of the etching is detected, to a period of etching of another etching target film. When the detector 102b detects end points of the etching for all etching target films, the plasma controller 102a ends the plasma etching.

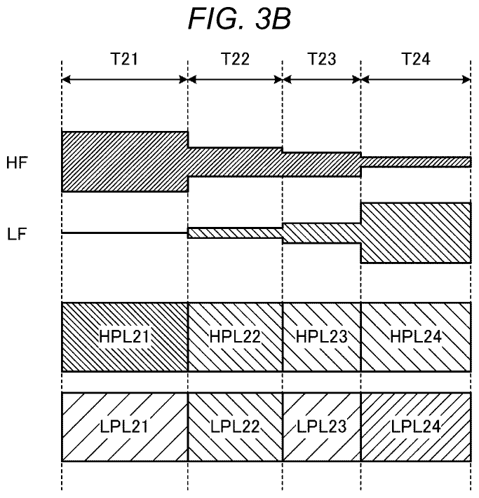

Here, an example of etching in which a power level is changed for each period during one cycle will be described. FIG. 4 is a diagram illustrating an example of the etching according to the embodiment. FIG. 4 illustrates a case where the source RF signal and the bias RF signal are turned on and off during one cycle to change a power level for each period during one cycle, and are supplied in a pulsed manner to generate a plasma. FIG. 4 illustrates a period in which the source RF signal and the bias RF signal are supplied. “HF” indicates a period in which the source RF signal is supplied. “LF” indicates a period in which the bias RF signal is supplied. The source RF signal and the bias RF signal are supplied during an On period. In FIG. 4, the source RF signal and the bias RF signal are supplied in pulses without overlapping with each other in periods. In FIG. 4, a frequency of a pulse for turning the source RF signal and the bias RF signal on and off is set to 1 kHz, and the source RF signal and the bias RF signal are turned on and off in a cycle of 1 ms, so that the etching is performed.

FIG. 4 illustrates tracking characteristics of radicals, ions, and electrons (Ion/Electron) in the plasma. The radicals follow On/Off of radio-frequency power in 1 ms or longer. Therefore, radicals generated at different power levels are mixed in one On/Off cycle. For example, in an On period of the LF, radicals in a period in which a preceding HF is On and radicals in which the LF is On are mixed. Therefore, when an end point of the etching is detected by targeting radicals such as by-products generated at a specific power level, radicals generated at another power level or tails around a signal wavelength thereof become noise. For example, in a period when the LF is On, radicals in a period when a previous HF is On become noise.

Meanwhile, tracking of ions and electrons with respect to On/Off of the radio-frequency power is 0.1 ms or less. Therefore, in the etching using an RF pulse of 100 Hz to 10 kHz, interference due to different power levels does not occur.

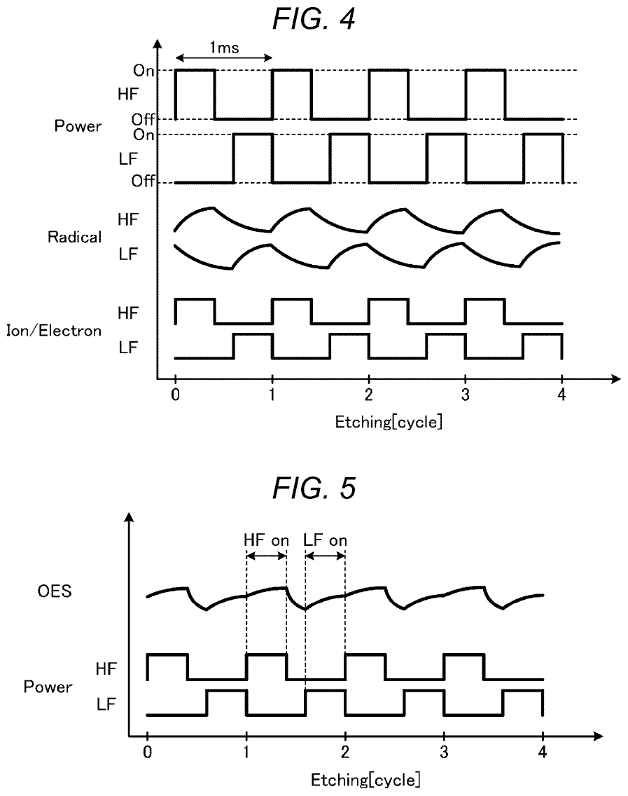

Here, detection of an end point of etching using an OES in the related art will be described for comparison. FIG. 5 is a diagram illustrating detection of the end point of the etching in the related art. When a power level is changed for each period during one cycle, radicals generated at different power levels are mixed in the plasma as described above. Therefore, even if an attempt is made to detect the end point of the etching based on a change in a detected emission intensity by detecting the emission intensity of a plasma during the etching using the OES, the end point of etching cannot be detected with high accuracy. For example, even if an attempt is made to detect the end point of the etching based on a change in an emission intensity of a plasma in an On period of the LF, light emission due to radicals in an On period of the HF is mixed in the On period of the LF, and thus the end point of the etching cannot be accurately detected.

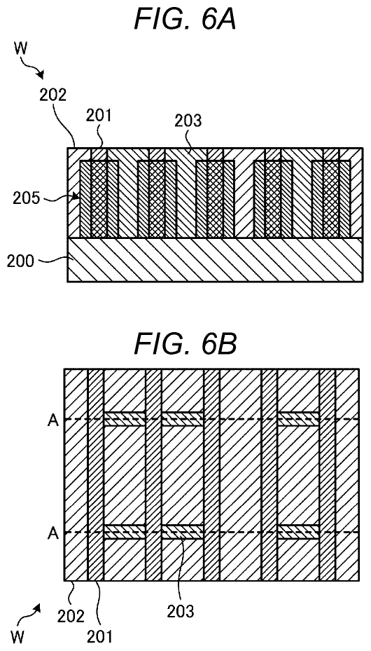

Next, an example of detecting the end point of the etching according to the present embodiment will be described. First, an example of the substrate W that is an etching target will be described. FIGS. 6A and 6B are diagrams illustrating examples of a schematic configuration of the substrate W that is the etching target according to the embodiment. FIG. 6B is a plan view of the substrate W viewed from above. FIG. 6A is a cross-sectional view illustrating a cross section of the substrate W taken along a line A shown in FIG. 6B.

The substrate W has an underlying film 200 on which linear structures 205 are formed in parallel. A first film 201 is formed on an upper portion of each structure 205. Between the structures 205, a second film 202 is formed up to a position higher than an upper surface of the structure 205. A third film 203 is formed in a portion between the structures 205. The first film 201 and the second film 202 are etching target films, respectively. For example, one of the first film 201 and the second film 202 is a nitride film, and the other is an oxide film. Which etching rate of the first film 201 and the second film 202 becomes dominant depends on a power level supplied during the etching. The third film 203 is, for example, a mask film.

Such a substrate W is used as a mask together with the third film 203 to etch the first film 201 and the second film 202. For example, the plasma processing apparatus 1 etches the first film 201 and the second film 202 by supplying a processing gas for etching into the plasma processing chamber 10 while supplying periodic power from the power supply 30 to the plasma processing chamber 10, a power level of the periodic power being changed for each period during one cycle. For example, the power supply 30 supplies a direct-current voltage, a voltage level of which is changed for each period during one cycle, from the first DC generator 32a to the lower electrode in the substrate support 11. The power supply 30 supplies a source RF signal, a power level of power of which is changed for each period during one cycle, from the first RF generator 31a to the conductive member of the shower head 13 via the conductive portion 33a. The power supply 30 supplies a bias RF signal, a power level of power of which is changed for each period during one cycle, from the second RF generator 31b to the conductive member of the base 1110 of the substrate support 11 via the conductive portion 33b.

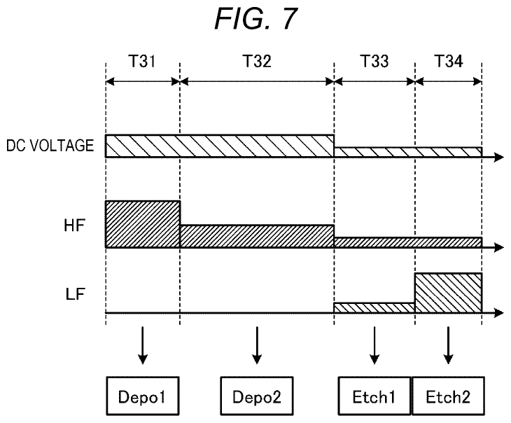

FIG. 7 is a diagram schematically illustrating an example of changes in periodic power supplied from the power supply 30 according to the embodiment. FIG. 7 illustrates changes in the periodic power supplied to the plasma processing chamber 10 during one cycle. “DC voltage” indicates a change in a direct-current voltage that is applied to the lower electrode in the substrate support 11. “HF” indicates a change in power of source RF signal power. “LF” indicates a change in power of bias RF signal power. In FIG. 7, one cycle of the periodic power is divided into periods T31 to T34. The DC voltage is set to a high voltage in the periods T31 and T32, and is set to a low voltage in the periods T33 and T34. The HF is set to large power in the period T31, set to medium power in the period T32, and set to small power in the periods T33 and T34. The LF is not supplied in the periods T31 and T32, is set to small power in the period T33, and is set to large power in the period T34. Which etching rate of the first film 201 and the second film 202 becomes dominant depends on power of bias RF signal power. For example, in the period T31 during one cycle, film formation 1 (Depo1) is performed on the substrate W. In the period T32, film formation 2 (Depo2) is performed on the substrate W. In the period T33, etching of the first film 201 of the substrate W (Etch1) is performed. The period T33 is a period that contributes most to etching and selectivity of the first film 201. In the period T34, etching of the second film 202 of the substrate W (Etch2) is performed. The period T34 is a period that contributes most to etching and selectivity of the second film 202.

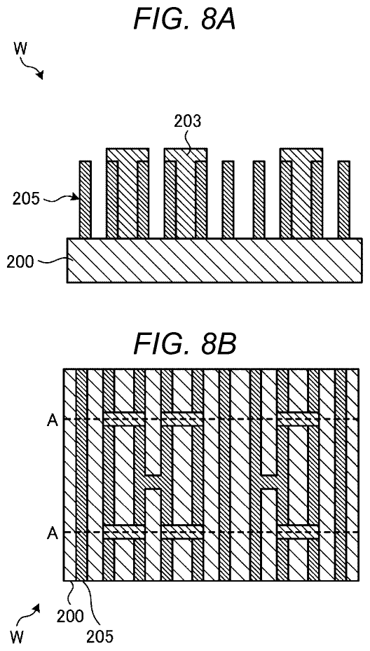

FIGS. 8A and 8B are diagrams illustrating examples of a schematic configuration of the etched substrate W according to the embodiment. FIG. 8B is a plan view of the substrate W viewed from above. FIG. 8A is a cross-sectional view showing a cross section of the substrate W taken along a line A shown in FIG. 8B. FIGS. 8A and 8B are results of etching the first film 201 and the second film 202 of the substrate W shown in FIGS. 6A and 6B. The first film 201 and the second film 202 are removed from the substrate W by etching.

The measurement unit 35a measures a voltage or a current of the conductive portion 33a through which the source RF signal flows. The measurement unit 35b measures a voltage or a current of the conductive portion 33b through which the bias RF signal flows. The measurement units 35a and 35b output signals indicating the measured voltage or current to the controller 100.

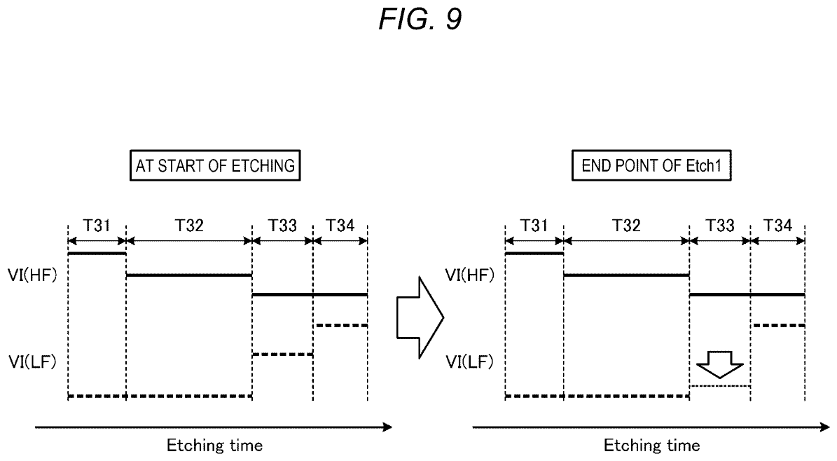

FIG. 9 is a diagram schematically illustrating changes in signals measured by the measurement units 35a and 35b according to the embodiment. FIG. 9 schematically illustrates changes in signals (VI signals) measured by the measurement units 35a and 35b in the periods T31 to T34 in one cycle at a start of the etching and at an end of the etching (Etch1) of the first film 201. VI(HF) schematically indicates a change in a signal measured by the measurement unit 35a provided in the conductive portion 33a through which the source RF signal flows. VI(LF) schematically indicates a change in a signal measured by the measurement unit 35b provided in the conductive portion 33b through which the bias RF signal flows.

During the etching, components of the etched first film 201 and second film 202 are continuously released into a plasma. When the etching of the first film 201 and the second film 202 is completed, there is no more release of the components of the first film 201 and the second film 202, and characteristics of the plasma are changed. Accordingly, the signals (VI signals) measured by the measurement units 35a and 35b change. For example, as illustrated in FIG. 9, the VI(LF) significantly changes in the period T33 as the etching of the first film 201 is completed. Therefore, by measuring at least one change in a voltage, a current, and a phase difference between the voltage and the current measured by the measurement unit 35b in the period T33, an end point of the etching of the first film 201 can be detected.

The detector 102b detects a state of the plasma processing based on voltages or currents of signals input from the measurement units 35a and 35b. For example, the detector 102b detects an end point of the plasma processing based on voltages or currents of signals input from the measurement units 35a and 35b. For example, the detector 102b detects the end point of the plasma processing based on a change in at least one of a voltage, a current, and a phase difference between the voltage and the current measured by the measurement units 35a and 35b at a timing synchronized with a cycle of periodic power supplied from the power supply 30 to the plasma processing chamber 10. For example, the detector 102b detects an end point of the etching of the first film 201 based on a change in a signal measured by the measurement unit 35b at a timing in the period T33 when a combination of the source RF signal and the bias RF signal contributes most to the etching and selectivity of the first film 201. For example, the detector 102b monitors, in real time, a voltage, a current, and a phase difference between the voltage and the current measured in the period T33 and detects a moment when there is a significant change as an end point of the etching of the first film 201. The detector 102b detects an end point of the etching of the second film 202 based on a change in a signal measured by the measurement unit 35b at a timing in the period T34 when a combination of the source RF signal and the bias RF signal contributes most to the etching and selectivity of the second film 202. For example, the detector 102b monitors, in real time, a voltage, a current, and a phase difference between the voltage and the current measured in the period T34, and detects a moment when there is a significant change as an end point of the etching of the second film 202. The detector 102b may apply a general mathematical method for reducing noise, such as a moving average or time differentiation, to data processing for detecting an end point. The measurement unit 35 may extract a signal having a specific frequency by passing a signal of a voltage or a signal of a current through a frequency filter.

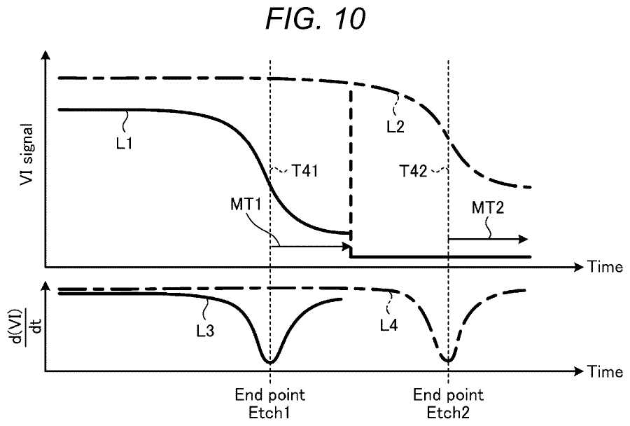

FIG. 10 is a diagram illustrating an example of detection of an end point of etching of the first film 201 and the second film 202 according to the embodiment. FIG. 10 illustrates a line L1 schematically illustrating, during the etching of the substrate W, a change over time of the signal (VI signal) periodically measured by the measurement unit 35b in the period T33, and a line L2 schematically illustrating a change over time of the signal (VI signal) measured in the period T34. The lines L1 and L2 indicate, for example, changes in average values in the periods T33 and T34, respectively. FIG. 10 illustrates a line L3 that indicates time differentiation of the line L1, and a line L4 that indicates time differentiation of the line L2. The line L3 indicates an amount of change in the line L1 per unit time. The line L4 indicates an amount of change in the line L2 per unit time.

The detector 102b detects the end point of the etching of the first film 201 based on a change in a signal measured by the measurement unit 35b at a timing in the period T33. For example, the detector 102b time-differentiates a signal shown by the line L1 to obtain an amount of change per unit time shown by the line L3 and detects the end point of the etching of the first film 201 with reference to a timing T41 when the amount of change becomes an extreme value. For example, the plasma processing apparatus 1 detects a timing when a desired margin time MT1 elapses from the timing T41 as the end point of the etching of the first film 201. The margin time MT1 is an elapsed time when the etching of the first film 201 is deemed to be completed from the timing T41. The margin time MT1 is determined by, for example, an experiment or a simulation.

The detector 102b detects the end point of the etching of the second film 202 based on a change in a signal measured by the measurement unit 35b at a timing in the period T34. For example, the detector 102b time-differentiates a signal shown by the line L2 to obtain an amount of change per unit time shown by the line L4 and detects the end point of the etching of the second film 202 with reference to a timing T42 when the amount of change becomes an extreme value. For example, the plasma processing apparatus 1 detects a timing when a desired margin time MT2 elapses from the timing T42 as the end point of the etching of the second film 202. The margin time MT2 is an elapsed time when the etching of the second film 202 is deemed to be completed from the timing T42. The margin time MT2 is determined by, for example, an experiment or a simulation.

The detector 102b may detect the timing T41 or the timing T42 when the amount of change becomes an extreme value, as the end point of the etching of the first film 201 or the second film 202. The detector 102b may detect a timing when changes in the signals illustrated by the lines L1 and L2 are saturated as the end points of the etching of the first film 201 and the second film 202.

Here, for example, when the end point of the etching is detected based on a moving average of the signals continuously measured by the VI probe as in the related art, the signals in the periods T31 and T32 other than a period in which the LF is supplied become noise, and the end point of the etching cannot be accurately detected.

Meanwhile, in the etching according to the present embodiment shown in FIGS. 8A and 8B, the period T33 contributes most to the etching and selectivity of the first film 201, and the period T34 contributes most to the etching and selectivity of the second film 202. Therefore, the detector 102b can detect an end of the etching of the first film 201 or the second film 202 with high accuracy by detecting an end of the etching based on a change in at least one of a voltage, a current, and a phase difference between the voltage and the current measured in the periods T33 and T34.

The plasma controller 102a controls the plasma processing based on a detection result from the detector 102b. For example, when the detector 102b detects an end point of first etching, the plasma controller 102a executes control to shorten or delete a period in which the etching of the first film 201 is performed during one cycle or allocate the period to another period during one cycle. When the end point of the etching of the second film 202 is detected, the plasma controller 102a executes control to shorten or delete a period in which the etching of the second film 202 is performed during one cycle or allocate the period to another period during one cycle.

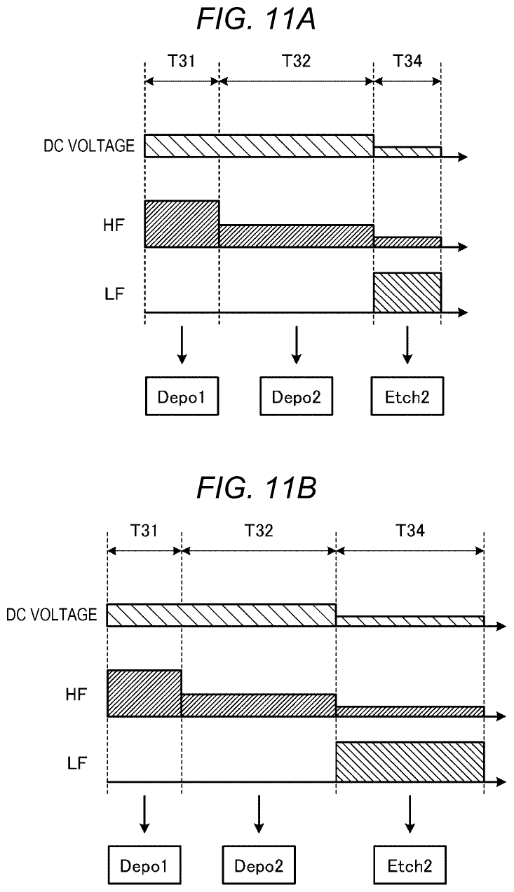

FIGS. 11A and 11B are diagrams schematically illustrating examples of changes in periodic power supplied from the power supply 30 according to the embodiment.

FIG. 11A illustrates a case where the period T33 in which the etching of the first film 201 is performed during one cycle is deleted when the end point of the first etching is detected. Accordingly, the period of one cycle is shortened, and the etching of the second film 202 is performed in a short cycle, so that the etching of the second film 202 proceeds quickly.

FIG. 11B illustrates a case where, when the end point of the first etching is detected, the period T33 in which the etching of the first film 201 is performed during one cycle is allocated to the period T34. Accordingly, since the period T34 in which the second film 202 is etched in the period of one cycle increases, the etching of the second film 202 proceeds quickly.

When the detector 102b detects the end point of the etching of the first film 201 and the second film 202, the plasma controller 102a ends the plasma etching.

In the above embodiment, a case where the end point of the plasma processing is detected based on the signals input from the measurement units 35a and 35b in the periods T33 and T34 during one cycle, synchronized with a cycle of the power supplied from the power supply 30 to the plasma processing chamber 10 is described as an example. However, the present disclosure is not limited thereto. The detector 102b may use a specific signal as a trigger and detect the end point of the plasma processing based on the signals input from the measurement units 35a and 35b at timings after a predetermined period from the trigger.

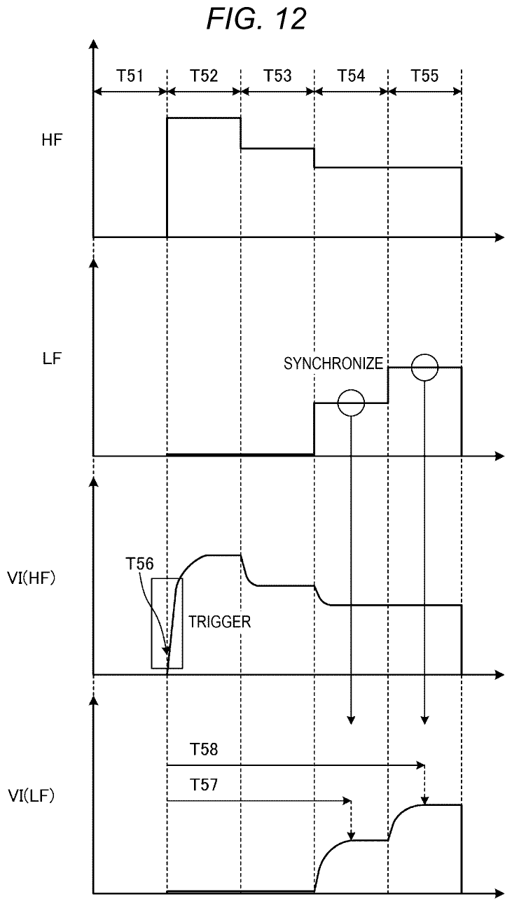

FIG. 12 illustrates an example of detecting an end point of etching according to the embodiment. FIG. 12 illustrates changes in periodic power supplied to the plasma processing chamber 10 during one cycle. “HF” indicates a change in power of source RF signal power. “LF” indicates a change in power of bias RF signal power. In FIG. 12, one cycle of the periodic power is divided into periods T51 to T55. The HF is not supplied in the period T51, is set to large power in the period T52, is gradually reduced in the periods T53 and T54, and is set to the same power as the period T54 in the period T55. The LF is not supplied in the periods T51 to T53, is set to medium power in the period T54, and is set to large power in the period T55. Different etching target films are etched in the periods T54 and T55. For example, in the period T54, etching of the first film 201 of the substrate W is performed. In the period T55, etching of the second film 202 of the substrate W is performed. FIG. 12 schematically illustrates changes in signals (VI signals) measured by the measurement units 35a and 35b in the periods T51 to T55. VI(HF) schematically indicates a change in a signal measured by the measurement unit 35a provided in the conductive portion 33a through which the source RF signal flows. VI(LF) schematically indicates a change in a signal measured by the measurement unit 35b provided in the conductive portion 33b through which the bias RF signal flows. In the VI(HF), the signal changes significantly in the period T52 when the source RF signal is supplied. With this change in signal as a trigger, an end point of the plasma processing may be detected based on signals input from the measurement units 35a and 35b at timings after a predetermined period from the trigger. For example, the end point of the etching of the first film 201 is detected based on a signal input from the measurement unit 35b at a timing when a desired time T57 elapses from a timing T56 when a signal measured by the measurement unit 35a rises by a desired amount or more. The end point of the etching of the second film 202 is detected based on a signal input from the measurement unit 35b at a timing when a desired time T58 elapses from the timing T56. The time T57 is an elapsed time since the timing T56 until the period T54. The time T58 is an elapsed time since the timing T56 until the period T55. The times T57 and T58 are determined by, for example, an experiment or a simulation.

The detector 102b may sample values of the signals input from the measurement units 35a and 35b during one cycle and detect the end point of the plasma processing based on changes in the values sampled during the one cycle.

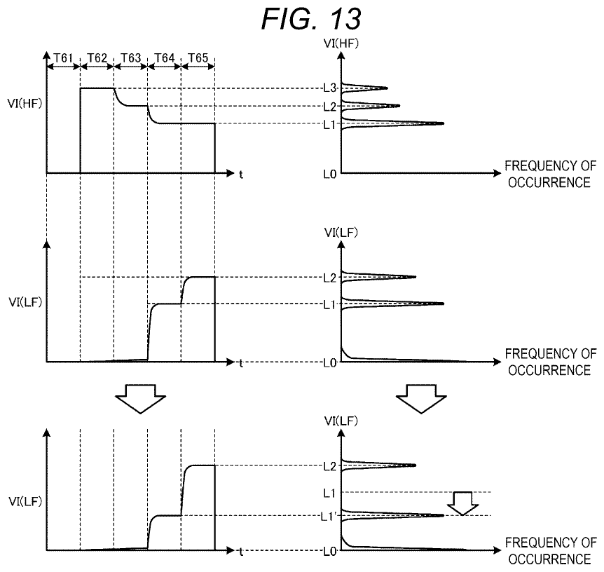

FIG. 13 illustrates an example of detecting an end point of etching according to the embodiment. FIG. 13 schematically illustrates changes in signals (VI signals) measured by the measurement units 35a and 35b during one cycle of periodic power supplied to the plasma processing chamber 10. VI(HF) schematically indicates a change in a signal measured by the measurement unit 35a provided in the conductive portion 33a through which the source RF signal flows. VI(LF) schematically indicates a change in a signal measured by the measurement unit 35b provided in the conductive portion 33b through which the bias RF signal flows. In FIG. 13, one cycle of the periodic power is divided into periods T61 to T65. For example, in the period T64, etching of the first film 201 of the substrate W is performed. In the period T65, etching of the second film 202 of the substrate W is performed. For example, when the etching of the first film 201 of the substrate W is completed, as illustrated in FIG. 13, the VI(LF) changes in the period T64.

The detector 102b samples values of the signals input from the measurement units 35a and 35b during one cycle and detects the end point of the plasma processing based on changes in the values sampled during one cycle. For example, the detector 102b samples the values of the signals input from the measurement units 35a and 35b during one cycle and calculates a frequency of occurrence of the values during one cycle based on sampled data. FIG. 13 shows a frequency of occurrence of values of the VI(HF) and the VI(LF) during one cycle. The detector 102b obtains a group having a high frequency of occurrence and obtains a representative value for each group. The representative value may be, for example, an average value or a median value of the group. In FIG. 13, representative values of groups having high frequencies of occurrence for the VI(HF) and the VI(LF) are indicated as L0, L1, L2, . . . . The detector 102b detects the end point of the plasma processing based on a change in the representative value for each group. For example, the detector 102b detects the end point of the etching of the first film 201 based on a change of the representative value L1 of the VI(LF) to L1′.

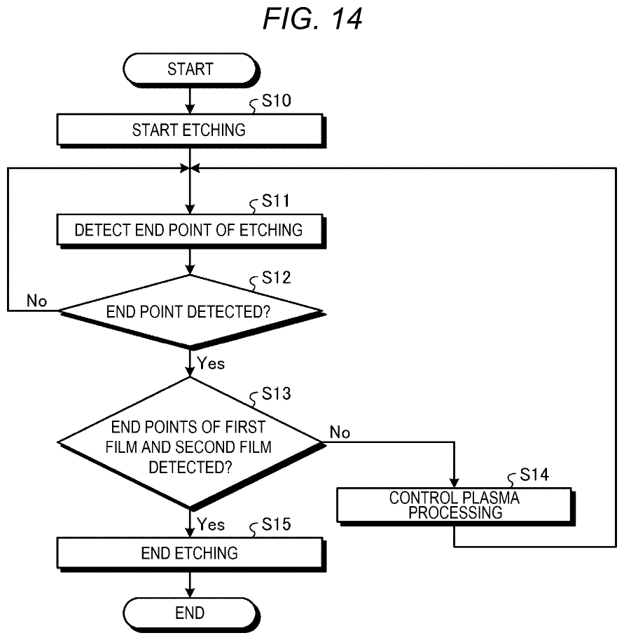

Next, a flow of processing of the end point detection method performed by the plasma processing apparatus 1 according to the embodiment will be described. FIG. 14 is a diagram illustrating an example of a processing order of the end point detection method according to the embodiment. In the plasma processing apparatus 1, the substrate W on which a first etching target film and a second etching target film are formed is placed on the substrate support 11. For example, in the plasma processing apparatus 1, the substrate W on which the first film 201 and the second film 202 illustrated in FIGS. 6A and 6B are formed is placed on the substrate support 11. The processing of the end point detection method shown in FIG. 14 is executed when etching is performed.

The plasma controller 102a starts etching (S10). For example, the plasma controller 102a controls the exhaust system 40 to exhaust an inside of the plasma processing chamber 10 to a desired vacuum level. The plasma controller 102a controls the gas supply 20 to introduce a processing gas for etching from the gas supply 20 into the plasma processing space 10s. The plasma controller 102a controls the power supply 30 to supply periodic power from the power supply 30 to the plasma processing chamber 10, a power level of the periodic power being changed for each period during one cycle, and which forms a plasma from a processing gas, and starts etching. For example, the plasma controller 102a controls the power supply 30 to supply the periodic power illustrated in FIG. 7 from the power supply 30 to the plasma processing chamber 10.

The detector 102b detects the end point of the plasma processing based on a change in at least one of a voltage, a current, and a phase difference between the voltage and the current measured by the measurement units 35a and 35b at a timing synchronized with a cycle of periodic power supplied from the power supply 30 to the plasma processing chamber 10 (S11). For example, the detector 102b detects the end point of the etching of the first film 201 based on a change in a signal measured by the measurement unit 35b at a timing in the period T33. The detector 102b detects the end point of the etching of the second film 202 based on a change in a signal measured by the measurement unit 35b at a timing in the period T34.

The plasma controller 102a determines whether an end point of the etching is detected by the detector 102b (S12). If the end point of the etching is not detected (S12: No), the processing proceeds to S11.

Meanwhile, if the end point of the etching is detected (S12: Yes), the plasma controller 102a determines whether an end points of the etching of the first film 201 and the second film 202 are detected (S13). If the end points of the etching of the first film 201 and the second film 202 are not detected (S13: No), the processing proceeds to S14.

Based on a detection result from the detector 102b, the plasma controller 102a controls the plasma processing (S14) and proceeds to S11. For example, if the detector 102b detects the end point of the etching of the first film 201, the plasma controller 102a executes control to shorten or delete a period in which the etching of the first film 201 is performed during one cycle or allocate the period to a period in which the etching of the second film 202 is performed. If the end point of the etching of the second film 202 is detected, the plasma controller 102a executes control to shorten or delete a period in which the etching of the second film 202 is performed during one cycle or allocate the period to a period in which the etching of the first film 201 is performed.

Meanwhile, if the end points of the etching of the first film 201 and the second film 202 are detected (S13: Yes), the plasma controller 102a ends the etching (S15) and ends the processing. For example, if the end points of the etching of the first film 201 and the second film 202 are detected, the plasma controller 102a ends the etching.

In the above embodiment, a case where the end point of the etching is detected based on a change in at least one of a voltage, a current, and a phase difference between the voltage and the current measured by the measurement units 35a and 35b is described as an example. However, the present disclosure is not limited thereto. A maximum value, a cycle (frequency), an average value, and an effective value of a waveform of each of a voltage and a current measured by the measurement units 35a and 35b vary before and after a timing of just-etching. Accordingly, the detector 102b may detect an end point of the etching based on a maximum value of either the voltage or the current, changes in the cycle (frequency), the average value, or the effective value, or a change in a phase difference between the voltage and the current. The detector 102b may detect the end point of the etching based on changes in an impedance value, a reactance value, a power value, and a power factor calculated based on the voltage, the current, and the phase difference between the voltage and the current. In this case as well, the detector 102b can detect the end point of the etching with high accuracy.

In the above embodiment, a case where the measurement units 35a and 35b are provided as the measurement unit 35 is described as an example. However, the present disclosure is not limited thereto. The measurement unit 35 may be provided in an electrode disposed in the plasma processing chamber 10 or an interconnect connected to the electrode in order to measure a state of a plasma in the plasma processing chamber 10. For example, an electrode for measurement may be disposed in the plasma processing chamber 10, and the measurement unit 35 may be provided in the electrode or an interconnect connected to the electrode. In the present embodiment, the measurement units 35a and 35b are provided closer to the plasma processing chamber 10 than the impedance matching circuits 34a and 34b. Accordingly, the measurement unit 35 can measure the state of the plasma in the plasma processing chamber 10.

In the above embodiment, a case where the measurement units 35a and 35b are provided as the measurement unit 35 to detect the end point of the etching is described as an example. However, the present disclosure is not limited thereto. Either of the measurement units 35a and 35b may detect the end point of the etching. For example, the end point of the etching may be detected only by the measurement unit 35b provided in the conductive portion 33b through which the bias RF signal contributing to the etching flows.

As described above, the plasma processing apparatus 1 according to the embodiment includes the plasma processing chamber 10, electrodes (the conductive member of the substrate support 11 and the conductive member of the shower head 13), the measurement units 35a and 35b, the gas supply 20, the power supply 30, and the detector 102b. The plasma processing chamber 10 has the substrate support 11 (stage) on which the substrate W is placed. The electrode is disposed in the plasma processing chamber 10. The measurement units 35a and 35b are provided in the electrodes or the conductive portions 33a and 33b (interconnects) connected to the electrodes, and measure at least one of a voltage and a current. The gas supply 20 supplies a gas to be formed into a plasma into the plasma processing chamber 10. The power supply 30 supplies, to the plasma processing chamber 10, periodic power for forming a gas supplied into the plasma processing chamber 10 into a plasma, a power level of the periodic power being changed for each period during one cycle. The detector 102b detects an end point of first etching based on at least one of a voltage, a current, and a phase difference between the voltage and the current measured by the measurement units 35a and 35b at a first timing during one cycle of the periodic power. The detector 102b detects an end point of second etching based on at least one of a voltage, a current, and a phase difference between the voltage and the current measured by the measurement units 35a and 35b at a second timing different from the first timing during one cycle. Accordingly, the plasma processing apparatus 1 can accurately detect the end point of the etching.

The substrate W has the first film 201 (first etching target film) and the second film 202 (second etching target film). The detector 102b detects an end point of the first etching, which is the end point of the etching of the first film 201, based on at least one of a voltage, a current, and a phase difference between the voltage and the current measured by the measurement units 35a and 35b at the first timing. The detector 102b detects an end point of the second etching, which is the end point of the etching of the second film 202, based on at least one of a voltage, a current, and a phase difference between the voltage and the current measured by the measurement units 35a and 35b at the second timing. Accordingly, the plasma processing apparatus 1 can accurately detect the end point of the etching of the first film 201 and the end point of the etching of the second film 202.

The substrate W has the first film 201 (first etching target film) and the second film 202 (second etching target film). The power supply 30 periodically supplies at least one of first power (source RF signal) having a first frequency for generating a plasma and second power (bias RF signal) having a second frequency lower than the first frequency for attracting an ion component in the plasma to the substrate W, with a power level being changed for each period during one cycle. The detector 102b detects the end point of the first etching, which is the end point of the etching of the first film 201, based on a change in at least one of a voltage, a current, and a phase difference between the voltage and the current measured by the measurement units 35a and 35b at the first timing (period T33) when a combination of the supplied first power and second power contributes most to the etching and selectivity of the first film 201. The detector 102b detects the end point of the second etching, which is the end point of the etching of the second film 202, based on a change in at least one of a voltage, a current, and a phase difference between the voltage and the current measured by the measurement units 35a and 35b at the second timing (period T34) when a combination of the supplied first power and second power contributes most to the etching and selectivity of the second film 202. Accordingly, the plasma processing apparatus 1 can accurately detect the end point of the etching of the first film 201 and the end point of the etching of the second film 202.

The detector 102b detects the end point of the first etching and the end point of the second etching based on a change in at least one of a voltage, a current, and a phase difference between the voltage and the current measured by the measurement units 35a and 35b in a period in which the second power is supplied. Accordingly, the plasma processing apparatus 1 can accurately detect the end point of the etching of the first film 201 and the end point of the etching of the second film 202.

The plasma processing apparatus 1 further includes the plasma controller 102a. When the detector 102b detects the end point of the first etching, the plasma controller 102a executes control to shorten or delete a period in which the first etching is performed during one cycle, or allocate the period to another period during one cycle, and when the detector 102b detects the end point of the second etching, the plasma controller 102a executes control to shorten or delete a period in which the second etching is performed during one cycle, or allocate the period to another period during one cycle. Accordingly, the plasma processing apparatus 1 can accelerate a progress of the etching of the first film 201 and the second film 202.

The first timing and the second timing are synchronized with the cycle of the power. Accordingly, the plasma processing apparatus 1 can accurately detect the end point of the etching of the first film 201 and the end point of the etching of the second film 202.

The first timing and the second timing are timings after the respective predetermined periods from a trigger, using specific signals from the measurement units 35a and 35b as the trigger. Accordingly, the plasma processing apparatus 1 can detect the end point of the etching with high accuracy by detecting a specific signal even if a cycle of power is not detected.

The electrode is provided on the substrate support 11. The conductive portion 33b (interconnect) connected to the electrode is provided with the impedance matching circuit 34b (matching circuit), and power is supplied from the power supply 30. The measurement unit 35b is provided closer to the electrode than the impedance matching circuit 34b of the conductive portion 33b. Accordingly, the measurement unit 35b can accurately measure changes in voltage and current caused by changes in a state of a plasma in the plasma processing chamber 10. Accordingly, the plasma processing apparatus 1 can detect the end point of the etching with high accuracy.

The embodiment has been described above. The embodiment disclosed herein is illustrative and should not be construed as limiting in all aspects. The embodiment described above may be embodied in various forms. Constituent parts of the embodiment described above may be omitted, replaced, or modified in various forms without departing from the scope and spirit of the claims.

For example, in the above embodiment, a case where the plasma processing is performed on a semiconductor wafer serving as the substrate W is described as an example, but the present disclosure is not limited thereto. The substrate W may be any substrate.

In the above embodiment, a case where the plasma processing apparatus 1 includes, in the power supply 30, the first RF generator 31a and the second RF generator 31b for generating a plasma and is configured to generate a plasma by radio frequency (RF) is described as an example. However, the present disclosure is not limited thereto. The plasma processing apparatus 1 may generate a plasma by microwaves and may be configured to attract ion components in the plasma to the substrate W by applying a rectangular direct-current voltage to the conductive member of the substrate support 11. For example, the plasma processing apparatus 1 may be configured such that the first RF generator 31a is replaced with a microwave power supply, and the second RF generator 31b is replaced with a direct-current power supply that applies a rectangular direct-current voltage.

In the above embodiment, a case where the first film 201 and the second film 202 formed on the substrate W are etched as the first etching target film and the second etching target film is described as an example. However, the present disclosure is not limited thereto. One or more etching target films are further formed on the substrate W, and the one or more etching target films may be etched by periodic power, a power level of which is changed for each period during one cycle. For example, a third etching target film may be further formed on the substrate W. The detector 102b may detect an end point of third etching, which is an end point of etching of the third etching target film, based on a change in at least one of a voltage, a current, and a phase difference between the voltage and the current measured by the measurement units 35a and 35b at a third timing during one cycle, which is different from the first timing and the second timing. For example, the detector 102b may detect the end point of the third etching based on a change in at least one of a voltage, a current, and a phase difference between the voltage and the current measured by the measurement units 35a and 35b in a period in which the second power (bias RF signal) is supplied. Accordingly, the plasma processing apparatus 1 can accurately detect the end point of the etching of the third etching target film.

It shall be understood that the embodiment disclosed herein are illustrative and are not restrictive in all aspects. Indeed, the above-described embodiment can be implemented in various forms. Constituent parts of the embodiment described above may be omitted, replaced, or modified in various forms without departing from the scope and spirit of the appended claims.

With respect to the above-described embodiment, the following appendices will be further disclosed.
Appendix 1

A plasma processing apparatus including:
a chamber having a stage inside on which a substrate is placed,
an electrode disposed in the chamber,
a measurement unit provided on the electrode or on an interconnect connected to the electrode, and configured to measure either a voltage or a current,
a gas supply configured to supply a gas to be formed into a plasma into the chamber,
a power supply configured to supply, to the chamber, periodic power for forming the gas supplied into the chamber into the plasma, a power level of the periodic power being changed for each period during one cycle, and
a detector configured to detect an end point of first etching based on at least one of a voltage, a current, and a phase difference between the voltage and the current measured by the measurement unit at a first timing during the one cycle of the periodic power, and configured to detect an end point of second etching based on at least one of a voltage, a current, and a phase difference between the voltage and the current measured by the measurement unit at a second timing different from the first timing during the one cycle.
Appendix 2

The plasma processing apparatus according to Appendix 1, in which
the substrate includes a first etching target film and a second etching target film, and
the detector detects the end point of the first etching, which is an end point of etching of the first etching target film, based on at least one of a voltage, a current, and a phase difference between the voltage and the current measured by the measurement unit at the first timing, and detects the end point of the second etching, which is an end point of etching of the second etching target film, based on at least one of a voltage, a current, and a phase difference between the voltage and the current measured by the measurement unit at the second timing.
Appendix 3

The plasma processing apparatus according to Appendix 1, in which
the substrate includes a first etching target film and a second etching target film,
the power supply periodically supplies at least one of first power having a first frequency for generating a plasma and second power having a second frequency lower than the first frequency for attracting an ion component in the plasma to the substrate by changing a power level for each period during one cycle, and
the detector detects the end point of the first etching, which is an end point of etching of the first etching target film, based on a change in at least one of a voltage, a current, and a phase difference between the voltage and the current measured by the measurement unit at the first timing when a combination of the supplied first power and second power contributes most to etching and selectivity of the first etching target film, and detects the end point of the second etching, which is an end point of etching of the second etching target film, based on a change in at least one of a voltage, a current, and a phase difference between the voltage and the current measured by the measurement unit at the second timing when a combination of the supplied first power and second power contributes most to etching and selectivity of the second etching target film.
Appendix 4

The plasma processing apparatus according to Appendix 3, in which
the detector detects the end point of the first etching and the end point of the second etching based on a change in at least one of a voltage, a current, and a phase difference between the voltage and the current measured by the measurement unit in a period in which the second power is supplied.
Appendix 5

The plasma processing apparatus according to Appendix 3 or 4, in which
the power supply includes a first power supply that supplies the first power and a second power supply that supplies the second power,
the first power supply is a microwave power supply or a radio frequency (RF) power supply, and
the second power supply is a radio frequency (RF) power supply or a power supply configured to apply a direct-current voltage in a rectangular shape.
Appendix 6

The plasma processing apparatus according to any one of Appendices 1 to 5, further including:
a plasma controller configured to execute control to, when the detector detects the end point of the first etching, shorten or delete a period in which the first etching is performed during the one cycle, or allocate the period to another period during the one cycle, and execute control to, when the detector detects the end point of the second etching, shorten or delete a period in which the second etching is performed during the one cycle, or allocate the period to another period during the one cycle.
Appendix 7

The plasma processing apparatus according to any one of Appendices 1 to 6, in which
the first timing and the second timing are synchronized with a cycle of the power.
Appendix 8

The plasma processing apparatus according to any one of Appendices 1 to 6, in which
the first timing and the second timing are timings after predetermined periods from a trigger, using a specific signal from the measurement unit as the trigger.
Appendix 9

The plasma processing apparatus according to any one of Appendices 1 to 8, in which
the electrode is provided on the stage,
the interconnect connected to the electrode is provided with a matching circuit, and the power is supplied from the power supply, and
the measurement unit is provided closer to the electrode than the matching circuit on the interconnect.
Appendix 10

The plasma processing apparatus according to any one of Appendices 1 to 9, in which
the substrate further includes a third etching target film, and
the detector detects an end point of third etching, which is an end point of etching of the third etching target film, based on a change in at least one of a voltage, a current, and a phase difference between the voltage and the current measured by the measurement unit at a third timing during the one cycle, which is different from the first timing and the second timing.
Appendix 11

The plasma processing apparatus according to Appendix 10, in which
the detector detects the end point of the third etching based on a change in at least one of a voltage, a current, and a phase difference between the voltage and the current measured by the measurement unit in a period in which the second power is supplied.
Appendix 12

An end point detection method including:
supplying a gas to be formed into a plasma into a chamber having a stage inside on which a substrate is placed,
supplying to the chamber periodic power for forming the gas supplied into the chamber into the plasma, a power level of the periodic power being changed for each period during one cycle, and
detecting an end point of first etching based on at least one of a voltage, a current, and a phase difference between the voltage and the current measured by a measurement unit, which is provided on an electrode disposed in the chamber or on an interconnect connected to the electrode and configured to measure at least one of a voltage and a current, at a first timing during the one cycle of the periodic power, and detecting an end point of second etching based on at least one of a voltage, a current, and a phase difference between the voltage and the current measured by the measurement unit at a second timing different from the first timing during the one cycle.

1. A plasma processing apparatus comprising:
a chamber having a stage inside on which a substrate is placeable,
an electrode disposed in the chamber,
a sensor provided on the electrode or on an interconnect connected to the electrode, and configured to measure either a voltage or a current,
a gas supply configured to supply a gas to be formed into a plasma into the chamber,
a power supply configured to supply, to the chamber, periodic power for forming the gas supplied into the chamber into the plasma, a power level of the periodic power being changed for each period during one cycle, and
circuitry configured to:
detect an end point of a first etching based on at least one of a voltage, a current, or a phase difference between the voltage or the current measured by the sensor at a first timing during the one cycle, and
detect an end point of a second etching based on at least one of a voltage, a current, or a phase difference between the voltage or the current measured by the sensor at a second timing different from the first timing during the one cycle.

2. The plasma processing apparatus according to claim 1, wherein the circuitry is configured to:
perform etching of a first etching target film and a second etching target film,
detect the end point of the first etching, which is an end point of etching of the first etching target film, based on at least one of a voltage, a current, or a phase difference between the voltage or the current measured by the sensor at the first timing, and
detect the end point of the second etching, which is an end point of etching of the second etching target film, based on at least one of a voltage, a current, or a phase difference between the voltage or the current measured by the sensor at the second timing.

3. The plasma processing apparatus according to claim 1, wherein
the power supply periodically supplies at least one of first power having a first frequency for generating a plasma and second power having a second frequency lower than the first frequency for attracting an ion component in the plasma to the substrate by changing a power level for each period during one cycle, and
the circuitry is configured to:
perform etching of a first etching target film and a second etching target film,
detect the end point of the first etching, which is an end point of etching of the first etching target film, based on a change in at least one of a voltage, a current, or a phase difference between the voltage or the current measured by the sensor at the first timing when a combination of the first power and second power contributes most to etching and selectivity of the first etching target film, and
detect the end point of the second etching, which is an end point of etching of the second etching target film, based on a change in at least one of a voltage, a current, or a phase difference between the voltage or the current measured by the sensor at the second timing when a combination of the first power and second power contributes most to etching and selectivity of the second etching target film.

4. The plasma processing apparatus according to claim 3, wherein the circuitry is configured to detect the end point of the first etching and the end point of the second etching based on a change in at least one of a voltage, a current, or a phase difference between the voltage or the current measured by the sensor in a period in which the second power is supplied.

5. The plasma processing apparatus according to claim 3, wherein
the power supply includes a first power supply that supplies the first power and a second power supply that supplies the second power,
the first power supply is a microwave power supply or a radio frequency (RF) power supply, and
the second power supply is a radio frequency (RF) power supply or a power supply configured to apply a direct-current voltage in a rectangular shape.

6. The plasma processing apparatus according to claim 1, wherein the circuitry is configured to:
execute control to, when the end point of the first etching is detected, shorten or delete a period in which the first etching is performed during the one cycle, or allocate the period to another period during the one cycle, and
execute control to, when the end point of the second etching is detected, shorten or delete a period in which the second etching is performed during the one cycle, or allocate the period to another period during the one cycle.

7. The plasma processing apparatus according to claim 1, wherein
the first timing and the second timing are synchronized with a cycle of the power.

8. The plasma processing apparatus according to claim 1, wherein
the first timing and the second timing are timings after predetermined periods from a trigger that is a specific signal from the sensor.

9. The plasma processing apparatus according to claim 1, wherein
the electrode is provided on the stage,
the interconnect connected to the electrode is provided with a matching circuit, and
the sensor is provided closer to the electrode than the matching circuit on the interconnect.

10. The plasma processing apparatus according to claim 3, wherein the circuitry is configured to:
perform etching of a third etching target film, and
detect an end point of a third etching, which is an end point of etching of the third etching target film, based on a change in at least one of a voltage, a current, or a phase difference between the voltage or the current measured by the sensor at a third timing during the one cycle, which is different from the first timing and the second timing.

11. The plasma processing apparatus according to claim 10, wherein
the circuitry is configured to detect the end point of the third etching based on a change in at least one of a voltage, a current, or a phase difference between the voltage or the current measured by the sensor in a period in which the second power is supplied.

12. An end point detection method comprising:
supplying a gas to be formed into a plasma into a chamber having a stage inside on which a substrate is placed,
supplying, to the chamber, periodic power for forming the gas supplied into the chamber into the plasma, a power level of the periodic power being changed for each period during one cycle,
detecting an end point of a first etching based on at least one of a voltage, a current, or a phase difference between the voltage or the current measured by a sensor, which is provided on an electrode disposed in the chamber or on an interconnect connected to the electrode, at a first timing during the one cycle, and
detecting an end point of second etching based on at least one of a voltage, a current, or a phase difference between the voltage or the current measured by the sensor at a second timing different from the first timing during the one cycle.
